(19) United States
(12) Patent Application Publication
(10) Pub. No.: US 2026/0150308 A1
(43) Pub. Date: May 28, 2026

(54) METHOD FOR MANUFACTURING TRENCH CAPACITOR, TRENCH CAPACITOR, AND PACKAGE STRUCTURE

(71) Applicant: CXMT Corporation, Hefei City (CN)

(72) Inventors: Xiaolong CHEN, Hefei City (CN); Chunyang WANG, Hefei City (CN)

(73) Assignee: CXMT Corporation, Hefei City (CN)

(21) Appl. No.: 19/238,727

(22) Filed: Jun. 16, 2025

Related U.S. Application Data
(63) Continuation of application No. PCT/CN2025/080722, filed on Mar. 5, 2025.

(30) Foreign Application Priority Data
Nov. 27, 2024 (CN) 202411724295.7

(51) Int. Cl. H10D 1/66; H10D 1/00

(52) U.S. Cl. CPC H10D 1/665; H10D 1/047

(57) ABSTRACT

Provided is a method for manufacturing a trench capacitor. The method includes the steps as follows. A substrate is provided, where the substrate has a first trench. A first electrode layer is formed in the first trench, where the first electrode layer covers the first trench and a surface of the substrate. A first dielectric layer is formed, where the first dielectric layer covers the first electrode layer. A second dielectric layer is formed, where the second dielectric layer covers at least the first dielectric layer on the surface of the substrate, and the second dielectric layer has a thickness greater than that of the first dielectric layer. A second electrode layer is formed on the second dielectric layer, where the second electrode layer covers the second dielectric layer. A third dielectric layer is formed, where the third dielectric layer fills the remaining first trench.

### CROSS-REFERENCE TO RELATED APPLICATIONS

This application is a continuation of International Patent Application No. PCT/CN2025/080722 filed on Mar. 5, 2025, which claims priority to Chinese Patent Application No. 202411724295.7 filed on Nov. 27, 2024. The disclosures of the above-referenced applications are hereby incorporated by reference in their entirety.

### BACKGROUND

With the advancement of the semiconductor integrated circuit manufacturing technology, miniaturization of device dimensions has become the key to improving the integration density and device performance. The application of a deep trench capacitor (DTC, Deep Trench Capacitor) in the field of integrated circuits (IC) is becoming increasingly important with the improvement of chip integration. However, with the reduction of a distance between electrode plates, current leakage between the electrode plates has become an urgent problem to be solved.

### SUMMARY

Embodiments of the present disclosure relate to the field of packaging, and in particular, to a method for manufacturing a trench capacitor, a trench capacitor, and a package structure.

Embodiments of the present disclosure provide a method for manufacturing a trench capacitor, a trench capacitor, and a package structure, to at least help solve and reduce the problem of current leakage between electrode plates.

According to some embodiments of the present disclosure, an aspect of the embodiments of the present disclosure provides a method for manufacturing a trench capacitor, including the steps as follows.
A substrate is provided, where the substrate has a first trench;
a first electrode layer is formed in the first trench, where the first electrode layer covers the first trench and a surface of the substrate;
a first dielectric layer is formed, where the first dielectric layer covers the first electrode layer;
a second dielectric layer is formed, where the second dielectric layer covers at least the first dielectric layer located on the surface of the substrate, and the second dielectric layer has a thickness greater than that of the first dielectric layer;
a second electrode layer is formed on the second dielectric layer, where the second electrode layer covers the second dielectric layer;
a third dielectric layer is formed, where the third dielectric layer fills the remaining first trench.

Another aspect of the embodiments of the present disclosure provides a trench capacitor, including:
a substrate, where the substrate has a first trench;
a first electrode layer, where the first electrode layer covers the first trench and part of a surface of the substrate;
a first dielectric layer, where the first dielectric layer covers the first electrode layer;
a second dielectric layer, where the second dielectric layer covers at least a first sub-dielectric layer on the surface of the substrate, and the second dielectric layer has a thickness greater than that of the first dielectric layer;
a second electrode layer, where the second electrode layer covers the second dielectric layer; and
a third dielectric layer, where the third dielectric layer covers the second electrode layer and fills the remaining first trench.

Still another aspect of the embodiments of the present disclosure provides a package structure, including:
a circuit board;
a package substrate, where the package substrate is located on the circuit board;
an adapter board, where the adapter board includes the trench capacitor according to the first aspect; and
a memory, where the memory is located on the adapter board, and is electrically connected to the adapter board.

The technical solutions provided in the embodiments of the present disclosure have at least the following advantages. The first dielectric layer and the second dielectric layer are arranged between the first electrode layer and the second electrode layer, and the second dielectric layer has a thickness greater than that of the first dielectric layer, so that the dielectric layer between the first electrode layer and the second electrode layer on the surface of the substrate has a larger thickness, thereby preventing current leakage between the first electrode layer and the second electrode layer, and improving performance of the trench capacitor.

### BRIEF DESCRIPTION OF DRAWINGS

One or more embodiments are exemplified with the figures in the accompanying drawings corresponding to the one or more embodiments. These example descriptions are not intended to limit the embodiments, and unless specifically stated, no scale limitations are constituted by the figures in the accompanying drawings. To describe the technical solutions in the embodiments of the present disclosure or the conventional technologies more clearly, the accompanying drawings required by the embodiments are briefly described below. Clearly, the accompanying drawings in the following description show merely some embodiments of the present disclosure, and other drawings may be obtained by a person of ordinary skill in the art from these accompanying drawings without creative efforts.

FIG. 1 is a schematic diagram of a capacitor structure;

FIG. 2 is a first process flowchart of a method for manufacturing a trench capacitor according to an embodiment of the present disclosure;

FIG. 3 is a second process flowchart of a method for manufacturing a trench capacitor according to an embodiment of the present disclosure;

FIG. 4 is a third process flowchart of a method for manufacturing a trench capacitor according to an embodiment of the present disclosure;

FIG. 5 is a fourth process flowchart of a method for manufacturing a trench capacitor according to an embodiment of the present disclosure;

FIG. 6 is a fifth process flowchart of a method for manufacturing a trench capacitor according to an embodiment of the present disclosure;

FIG. 7 is a sixth process flowchart of a method for manufacturing a trench capacitor according to an embodiment of the present disclosure, and FIG. 7 is an enlarged view of a second dielectric layer in FIG. 6;

FIG. 8 is a seventh process flowchart of a method for manufacturing a trench capacitor according to an embodiment of the present disclosure;

FIG. 9 is an eighth process flowchart of a method for manufacturing a trench capacitor according to an embodiment of the present disclosure;

FIG. 10 is a nineth process flowchart of a method for manufacturing a trench capacitor according to an embodiment of the present disclosure;

FIG. 11 is a tenth process flowchart of a method for manufacturing a trench capacitor according to an embodiment of the present disclosure;

FIG. 12 is an eleventh process flowchart of a method for manufacturing a trench capacitor according to an embodiment of the present disclosure;

FIG. 13 is a twelfth process flowchart of a method for manufacturing a trench capacitor according to an embodiment of the present disclosure;

FIG. 14 is a thirteenth process flowchart of a method for manufacturing a trench capacitor according to an embodiment of the present disclosure;

FIG. 15 is a fourteenth process flowchart of a method for manufacturing a trench capacitor according to an embodiment of the present disclosure;

FIG. 16 is a fifteenth process flowchart of a method for manufacturing a trench capacitor according to an embodiment of the present disclosure;

FIG. 17 is a sixteenth process flowchart of a method for manufacturing a trench capacitor according to an embodiment of the present disclosure;

FIG. 18 is a first process flowchart of a method for forming a contact structure according to an embodiment of the present disclosure;

FIG. 19 is a second process flowchart of a method for forming a contact structure according to an embodiment of the present disclosure;

FIG. 20 is a third process flowchart of a method for forming a contact structure according to an embodiment of the present disclosure;

FIG. 21 is a fourth process flowchart of a method for forming a contact structure according to an embodiment of the present disclosure;

FIG. 22 is a fifth process flowchart of a method for forming a contact structure according to an embodiment of the present disclosure;

FIG. 23 is a sixth process flowchart of a method for forming a contact structure according to an embodiment of the present disclosure;

FIG. 24 is a schematic diagram of a trench capacitor according to an embodiment of the present disclosure; and

FIG. 25 is a schematic diagram of a package structure according to an embodiment of the present disclosure.

### DETAILED DESCRIPTION

According to the background, with the advancement of the semiconductor integrated circuit manufacturing technology, miniaturization of device dimensions has become the key to improving the integration density and device performance. The application of a deep trench capacitor (DTC, Deep Trench Capacitor) in the field of integrated circuits (IC) is becoming increasingly important with the improvement of chip integration. However, with the reduction of a distance between electrode plates, current leakage between the electrode plates has become an urgent problem to be solved.

Implementations of the present disclosure provide a method for manufacturing a trench capacitor, a trench capacitor, and a package structure. A first dielectric layer and a second dielectric layer are arranged between a first electrode layer and a second electrode layer, and the second dielectric layer has a thickness greater than that of the first dielectric layer, so that the dielectric layer between the first electrode layer and the second electrode layer on the surface of the substrate has a larger thickness, thereby preventing current leakage between the first electrode layer and the second electrode layer, and improving performance of the trench capacitor.

The embodiments of the present disclosure are described in detail below with reference to the accompanying drawings. However, it may be understood by a person of ordinary skill in the art that in the embodiments of the present disclosure, many technical details are provided to enable readers to better understand the present disclosure. However, the technical solutions claimed in the present disclosure may be implemented even without these technical details and various changes and modifications made based on the following embodiments. In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not drawn to exact scale, and are merely intended to conveniently and clearly assist in describing the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily indicate a specific order or sequence.

In the embodiments of the present disclosure, the term “layer” refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between a top surface and a bottom surface of the continuous structure, or the layer may be located between any horizontal surface pair at the top surface and the bottom surface of the continuous structure. The layer may extend horizontally, vertically, and/or along an inclined surface. The layer may include multiple sublayers.

It should be noted that the technical solutions described in the embodiments of the present disclosure may be arbitrarily combined when there is no conflict.

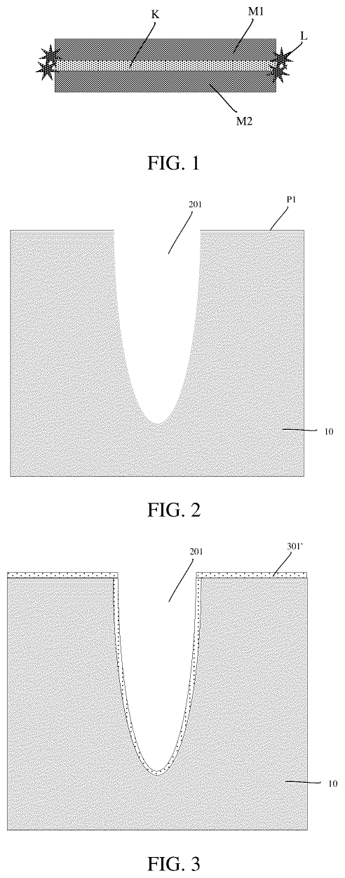

FIG. 1 is a schematic diagram of a capacitor structure.

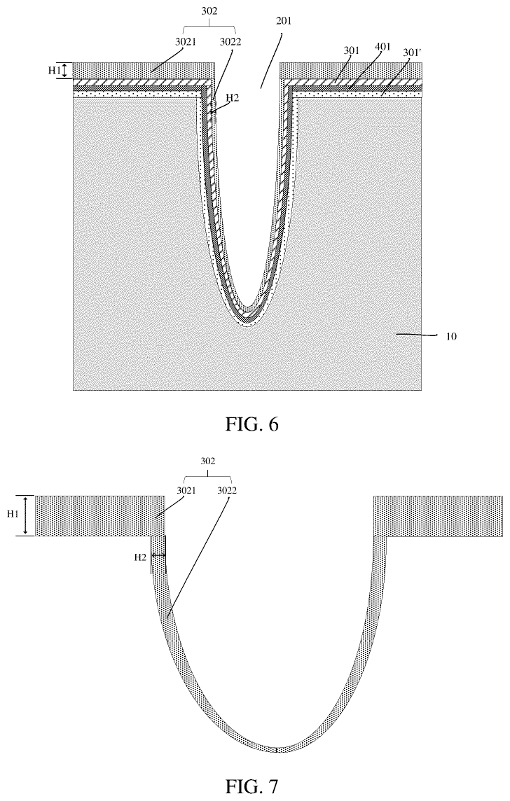

FIG. 2 to FIG. 17 are process flowcharts of a method for manufacturing a trench capacitor according to an embodiment of the present disclosure, where FIG. 7 is an enlarged view of a second dielectric layer in FIG. 6.

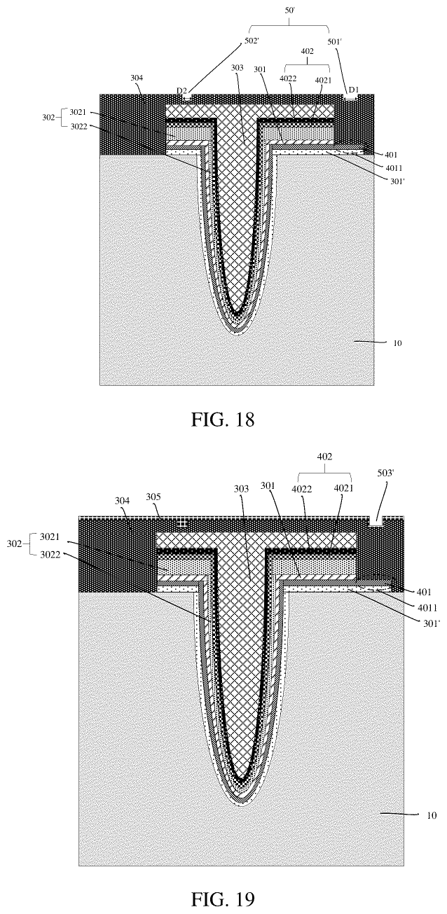

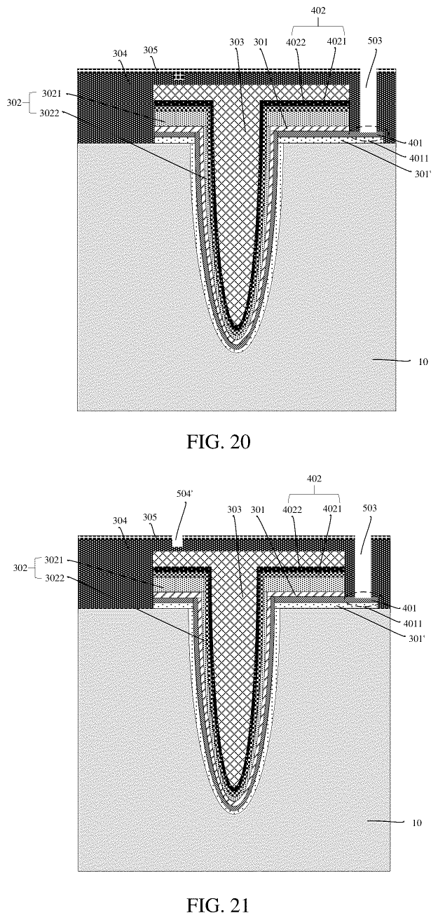

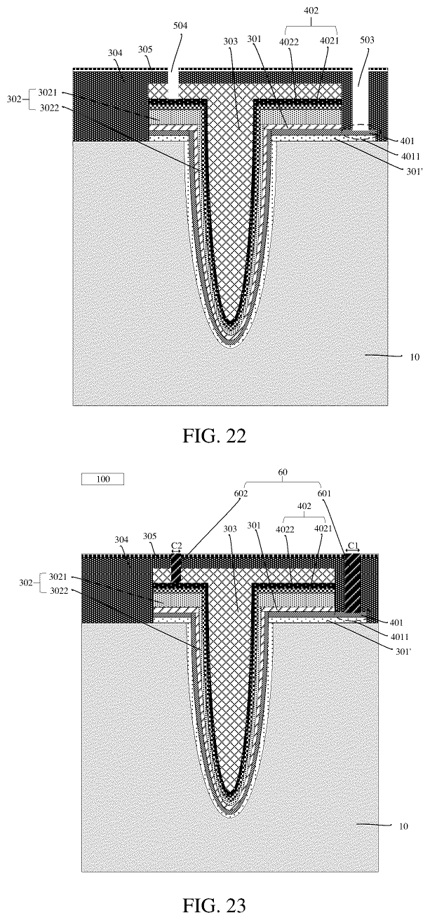

FIG. 18 to FIG. 23 are process flowcharts of a method for forming a contact structure according to an embodiment of the present disclosure.

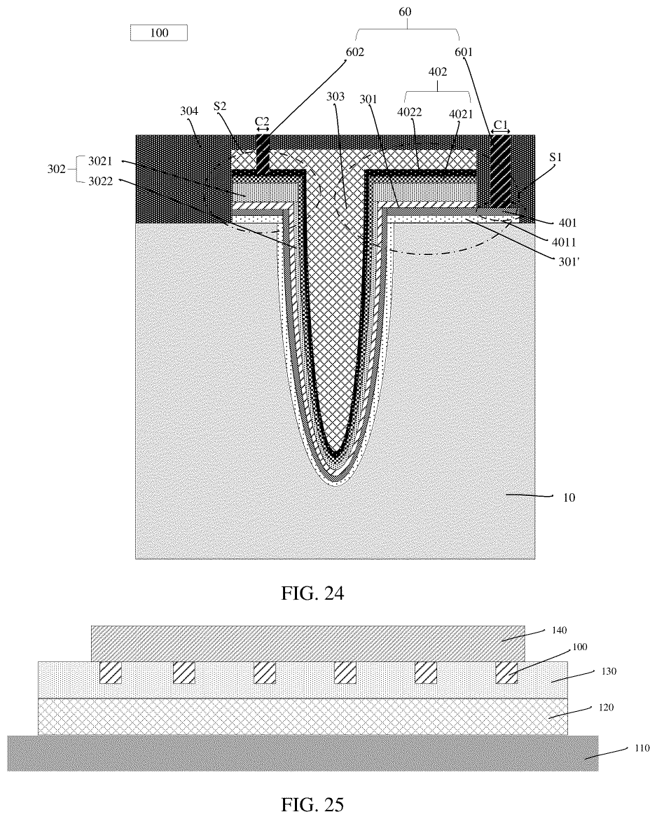

FIG. 24 is a schematic diagram of a trench capacitor according to an embodiment of the present disclosure.

FIG. 25 is a schematic diagram of a package structure according to an embodiment of the present disclosure.

FIG. 1 is a schematic diagram of a capacitor structure. Referring to FIG. 1, the capacitor structure generally includes an upper electrode plate M1, a lower electrode plate M2, and a dielectric layer K, but a leakage current L easily occurs at edges of the upper electrode plate and the lower electrode plate, and the leakage current L herein is only an example for description. The existence of the leakage current leads to charge loss, and energy loss is caused during charging or discharging of a capacitor, which degrades performance and stability of the capacitor structure. On the other hand, in the case of severe current leakage of the capacitor, the upper electrode plate and the lower electrode plate of the capacitor may be short-circuited, which affects normal use of the capacitor structure. With the miniaturization of semiconductor integrated devices, a deep trench capacitor (DTC, Deep Trench Capacitor) is increasingly applied widespread, but current leakage between electrode plates in the deep trench capacitor is still an urgent problem to be solved, and especially, an edge of the capacitor is a place where the leakage current is the most severe.

This application provides a method for manufacturing a trench capacitor to at least help solve the above-mentioned current leakage problem of the capacitor. The method for manufacturing a trench capacitor includes the steps as follows. A substrate is provided, where the substrate has a first trench. A first electrode layer is formed in the first trench, where the first electrode layer covers the first trench and a surface of the substrate. A first dielectric layer is formed, where the first dielectric layer covers the first electrode layer. A second dielectric layer is formed, where the second dielectric layer covers at least the first dielectric layer located on the surface of the substrate, and the second dielectric layer has a thickness greater than that of the first dielectric layer. A second electrode layer is formed on the second dielectric layer, where the second electrode layer covers the second dielectric layer. A third dielectric layer is formed, where the third dielectric layer fills the remaining first trench. FIG. 2 to FIG. 17 are process flowcharts of a method for manufacturing a trench capacitor according to an embodiment of the present disclosure, where FIG. 7 is an enlarged view of a second dielectric layer in FIG. 6.

Specifically, referring to FIG. 2, a substrate 10 is provided. The substrate 10 has a first surface P1, and a first trench 201 is provided from the first surface P1 of the substrate 10 to an interior of the substrate 10. The substrate 10 may be a silicon interposer, or may alternatively be made of a semiconductor material, an insulating material, or a combination thereof. For example, the substrate 10 may be a silicon (Si) substrate, a silicon germanium (SiGe) substrate, a silicon germanium carbon (SiGeC) substrate, a silicon carbide (SiC) substrate, a gallium arsenide (GaAs) substrate, an indium arsenide (InAs) substrate, an indium phosphide (InP) substrate, or another III/V semiconductor substrate or II/VI semiconductor substrate. Alternatively, for another example, the substrate 10 may be a layered substrate including, e.g., Si/SiGe, Si/SiC, silicon on insulator (SOI), or silicon germanium on insulator. A person skilled in the art may select a type of the substrate based on a type of a transistor formed on the substrate. Therefore, the type of the substrate should not limit the protection scope of this application.

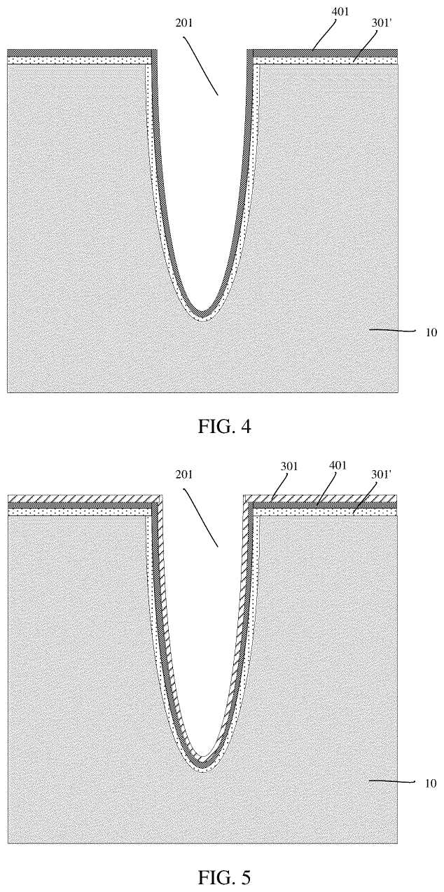

Next, referring to FIG. 4, a first electrode layer 401 is formed in the first trench 201. The first electrode layer 401 covers the first trench 201 and a surface of the substrate 10. The first electrode layer 401 may be made of titanium nitride or tungsten.

In a specific embodiment, referring to FIG. 3, before that a first electrode layer 401 is formed, the method further includes the step as follows. An initial dielectric layer 301′ is formed, where the initial dielectric layer 301′ covers the first trench 201 and the surface of the substrate 10. The initial dielectric layer 301′ may be made of one or more of silicon nitride, silicon oxide, or cobalt oxynitride.

Next, referring to FIG. 5, a first dielectric layer 301 is formed, where the first dielectric layer 301 covers the first electrode layer 401.

Next, referring to FIG. 6, a second dielectric layer 302 is formed on the first dielectric layer 301, where the second dielectric layer 302 covers at least the first dielectric layer 301 located on the surface of the substrate 10, and the second dielectric layer 302 has a thickness greater than that of the first dielectric layer 301. In a specific embodiment, the second dielectric layer 302 covers only the first dielectric layer 301 located on the surface of the substrate 10. In another specific embodiment, the second dielectric layer 302 includes a first sub-dielectric layer 3021 located on the surface of the substrate 10 and a second sub-dielectric layer 3022 located in the first trench 201. The first sub-dielectric layer 3021 has a thickness of H1, the second sub-dielectric layer 3022 has a thickness of H2. The thickness H1 of the first sub-dielectric layer 3021 is greater than the thickness H2 of the second sub-dielectric layer 3022. In a specific embodiment, the first dielectric layer 301 and the second dielectric layer 302 each may be made of a material with a high dielectric constant. For example, the first dielectric layer 301 and the second dielectric layer 302 each may be made of one or more of hafnium oxide, zirconium oxide, hafnium silicate, hafnium zirconate, lanthanum oxide, lanthanum silicate, barium strontium titanate, or lanthanum aluminate. There may be a single or multiple first dielectric layers 301 and a single or multiple second dielectric layers 302. In another specific embodiment, a dielectric constant of the first dielectric layer 301 is greater than a dielectric constant of the second dielectric layer 302. In a specific embodiment, the first dielectric layer 301 may be made of one or more of hafnium oxide, zirconium oxide, hafnium silicate, hafnium zirconate, lanthanum oxide, lanthanum silicate, barium strontium titanate, or lanthanum aluminate. There may be a single or multiple first dielectric layers 301. The second dielectric layer 302 may be made of one or more of silicon oxide, silicon nitride, or silicon oxynitride. There may be a single or multiple second dielectric layers 302.

FIG. 7 is an enlarged view of a second dielectric layer 302 in FIG. 6. It can be seen from the figure that the thickness H1 of the first sub-dielectric layer 3021 is greater than the thickness H2 of the second sub-dielectric layer 3022. The thickness H1 of the first sub-dielectric layer 3021 mentioned herein refers to a length of the first sub-dielectric layer 3021 in a direction perpendicular to the substrate 10, and the thickness H2 of the second sub-dielectric layer 3022 refers to a length of the second sub-dielectric layer 3022 in a direction parallel to the substrate 10. In a specific embodiment, the thickness of the second sub-dielectric layer 3022 gradually decreases from a top of the second sub-dielectric layer 3022 to a bottom of the first trench 201. It should be noted that the top of the second sub-dielectric layer 3022 mentioned herein refers to a position flush with a surface of the first dielectric layer 301. The thickness H1 of the first sub-dielectric layer 3021 is greater than the thickness of the second sub-dielectric layer 3022 at any position. In a specific embodiment, the thickness H1 of the first sub-dielectric layer 3021 is 3-8 times the thickness H2 of the second sub-dielectric layer 3022.

In a specific embodiment, the second dielectric layer 302 is formed by a first deposition process, and the first deposition process is plasma enhanced chemical vapor deposition (Plasma Enhanced Chemical Vapor Deposition, PECVD). The PECVD technology usually has a good deposition effect on a flat surface, but in a structure with a high aspect ratio, such as a deep trench capacitor (DTC, Deep Trench Capacitor), a trench filling capability of the technology is weak. This is mainly due to limited penetration power of plasma at the bottom of a deep hole or a trench, resulting in insufficient filling of the bottom of the deep hole or the trench. Due to the characteristics of the PECVD, the thickness H1 of the first sub-dielectric layer 3021 that is on the surface of the substrate 10 is greater than the thickness of the second sub-dielectric layer 3022 in the first trench 201, and the thickness of the second sub-dielectric layer 3022 gradually decreases from the top of the second sub-dielectric layer 3022 to the bottom of the first trench 201.

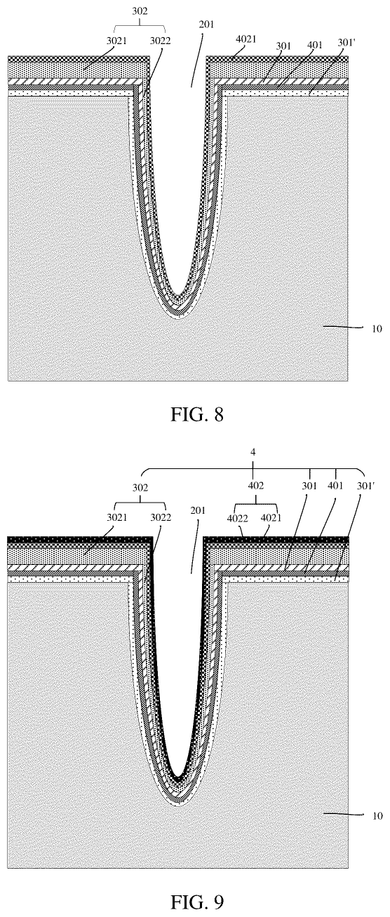

Next, referring to FIG. 8 and FIG. 9, a second electrode layer 402 is formed on the second dielectric layer 302. The second electrode layer 402 covers the second dielectric layer 302, and the second electrode layer 402 may be made of titanium nitride or tungsten. In a specific embodiment, the second electrode layer 402 includes a first sub-electrode layer 4021 and a second sub-electrode layer 4022. The first sub-electrode layer 4021 is formed on a surface of the second dielectric layer 302, and the second sub-electrode layer 4022 covers the first sub-electrode layer 4021. The first electrode layer 401, the second electrode layer 402, the first dielectric layer 301, and the second dielectric layer 302 form a capacitor structure. The first electrode layer 401, the second electrode layer 402, the first dielectric layer 301, the second dielectric layer 302, and the initial dielectric layer 301′ form a capacitor structure layer 4 together.

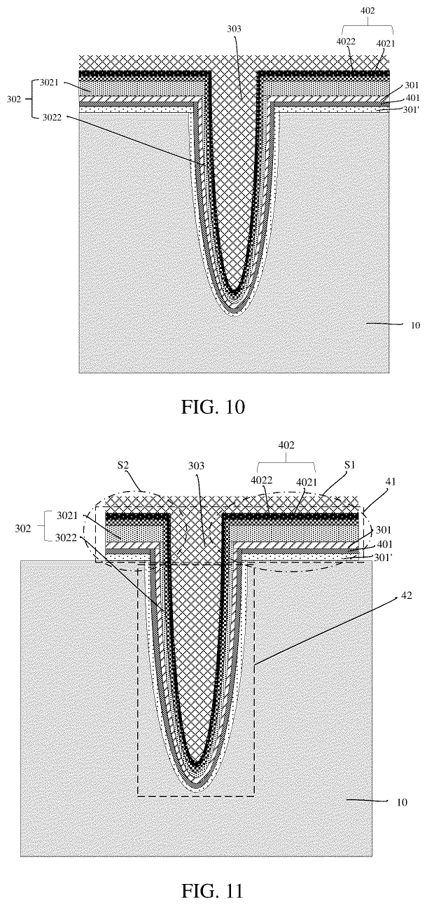

Next, referring to FIG. 10, a third dielectric layer 303 is formed. The third dielectric layer 303 fills the remaining first trench 201. The third dielectric layer 303 may be made of one or more of silicon nitride, silicon oxide, or silicon oxynitride.

Next, referring to FIG. 11, after the third dielectric layer 303 is formed, the method further includes the steps as follows. Part of the capacitor structure layer 4 and part of the third dielectric layer 303 on both sides of the first trench 201 are removed to expose part of the substrate 10. That is, an edge portion that is of the capacitor structure layer 4 and that is located on the surface of the substrate 10 is removed. The remaining capacitor structure layer 4 includes a first capacitor structure layer 41 located on the surface of the substrate 10 and a second capacitor structure layer 42 located in the first trench 201. The first capacitor structure layer 41 includes a first side S1 and a second side S2, and the first side S1 and the second side S2 are located on both sides of the first trench 201 respectively. A length of the first side S1 in a direction parallel to the substrate 10 is greater than a length of the second side S2 in the direction parallel to the substrate 10. Specifically, dashed lines in FIG. 11 show the first capacitor structure layer 41, the second capacitor structure layer 42, the first side S1, and the second side S2. The objective of removing part of the capacitor structure layer 4 and part of the third dielectric layer 303 on both sides of the first trench 201 to expose part of the substrate 10 is to cut off the adjacent capacitor structures to form independent capacitor structures.

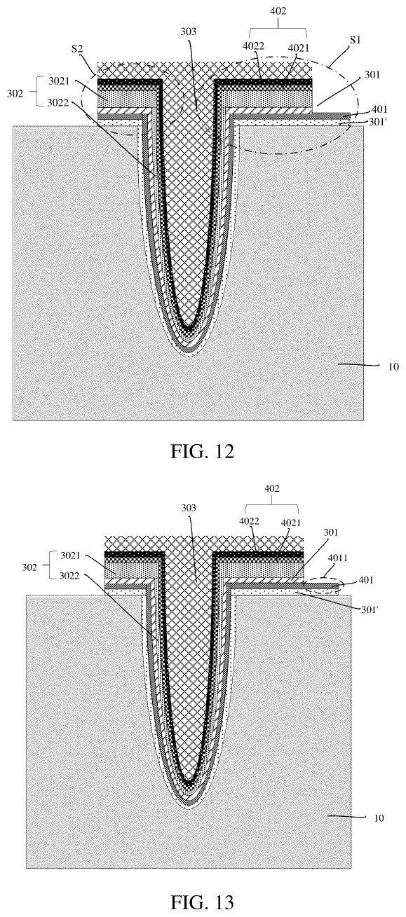

Next, referring to FIG. 12 and FIG. 13, part of the second electrode layer 402, part of the first dielectric layer 301, part of the second dielectric layer 302, and part of the third dielectric layer 303 on the first side S1 are removed, so that the first electrode layer 401 at an edge of the first side S1 is exposed, and the exposed first electrode layer 401 serves as an extension part 4011.

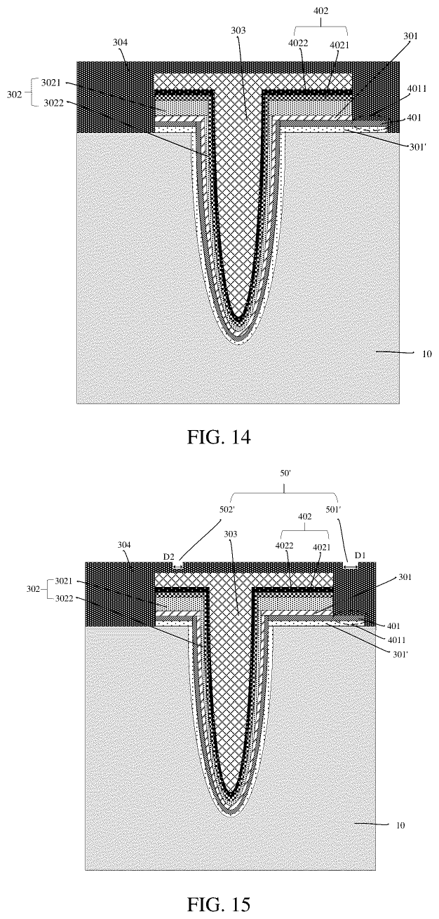

Next, referring to FIG. 14 to FIG. 17, the method further includes the step as follows. A contact structure 60 is formed. The contact structure 60 includes a first contact structure 601 and a second contact structure 602. The first contact structure 601 is electrically connected to the extension part 4011, and the second contact structure 602 is electrically connected to a second sub-electrode layer 4022 on the second side S2.

Specifically, referring to FIG. 14, a fourth dielectric layer 304 is formed. The fourth dielectric layer 304 covers the third dielectric layer 303, the extension part 4011, and part of the substrate 10.

Specifically, referring to FIG. 15, an initial opening 50′ is formed on the fourth dielectric layer 304. The initial opening 50′ includes a first initial opening 501′ and a second initial opening 502′, and an opening dimension D1 of the first initial opening 501′ is greater than an opening dimension D2 of the second initial opening 502′. The fourth dielectric layer 304 may be made of silicon nitride, silicon oxide, or silicon oxynitride.

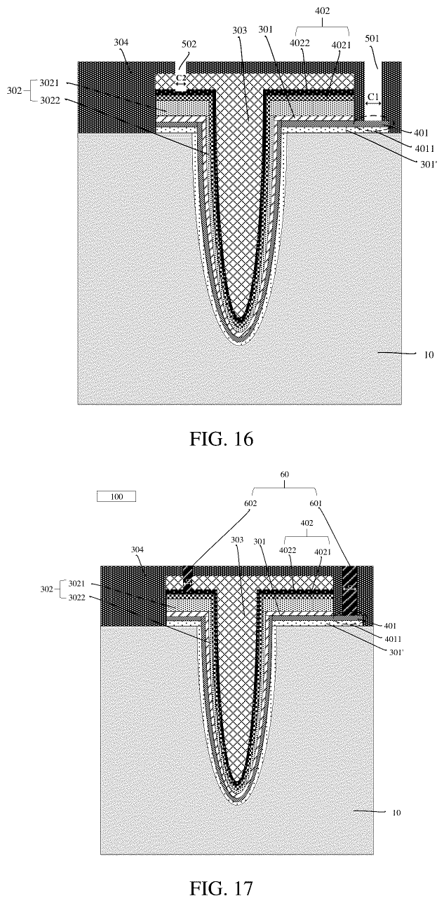

Next, referring to FIG. 16, etching continues to be performed along the initial opening 50′ to form a first opening 501 and a second opening 502. An opening dimension C1 of the first opening 501 is greater than an opening dimension C2 of the second opening 502. The first opening 501 exposes part of the extension part 4011, and the second opening 502 exposes the second sub-electrode layer 4022 on the second side S2. A projection of the first opening 501 on the first electrode layer 401 is located in the extension part 4011. That the opening dimension D1 of the first initial opening 501′ is greater than the opening dimension D2 of the second initial opening 502′ is because a larger opening dimension allows an etching gas to enter the opening more easily, resulting in a higher etching rate. The subsequently formed first opening 501 has a depth greater than that of the second opening 502. Therefore, to increase a formation rate of the first opening 501, the opening dimension D1 of the first initial opening 501′ is greater than the opening dimension D2 of the second initial opening 502′ when the initial opening 50′ is arranged.

Next, referring to FIG. 17, the first opening 501 and the second opening 502 are filled with a conductive material to form a first contact structure 601 and a second contact structure 602. The first contact structure 601 has a depth greater than that of the second contact structure 602. A width C1 of the first contact structure 601 is greater than a width C2 of the second contact structure 602. The first contact structure 601 and the second contact structure 602 form the contact structure 60 together, and the contact structure 60 may be made of titanium nitride or tungsten.

As shown in FIG. 17, the trench capacitor 100 is finally formed through the above-mentioned steps. In a specific embodiment, the second dielectric layer 302 is formed on the first dielectric layer 301. The second dielectric layer 302 covers only the first dielectric layer 301 on the surface of the substrate 10, and the second dielectric layer 302 has a thickness greater than that of the first dielectric layer 301. Originally, current leakage easily occurs between an upper electrode plate and a lower electrode plate at an edge of the trench capacitor. In this application, the second dielectric layer 302 is formed on the first dielectric layer 301, and the second dielectric layer 302 has a thickness greater than that of the first dielectric layer 301, so that the dielectric layer between the first electrode layer 401 and the second electrode layer 402, which is originally easily subjected to current leakage, has an increased thickness. This improves isolation performance between the first electrode layer 401 and the second electrode layer 402, and prevents the generation of a leakage current. For a person skilled in the art, a formula for determining capacitance is C=εS/4πkd, where ε denotes a dielectric constant of the dielectric layer, k denotes an electrostatic force constant, S denotes an overlapping projection area of the electrode plates, and d denotes a distance between the electrode plates. This formula is configured to calculate a capacitance value under a given dielectric layer, area, and distance. The capacitance of the capacitor is not only related to areas of the electrode plates, but also related to the thickness of the dielectric layer. Therefore, a smaller thickness indicates a larger capacitance value, and a larger thickness indicates a smaller capacitance value. In this application, the second dielectric layer 302 covers only the first dielectric layer 301 located on the surface of the substrate 10. That is, no second dielectric layer 302 exists in the first trench 201. That is, the thickness of the dielectric layer between the first electrode layer 401 and the second electrode layer 402 in the first trench 201 does not increase. This prevents the capacitance value from decreasing because the thickness of the dielectric layer increases, so as to ensure the capacitance value of the trench capacitor 100. That is, this application can not only solve the problem of current leakage between the first electrode layer 401 and the second electrode layer 402, but also ensure the capacitance value of the trench capacitor 100, thereby preventing the problem of capacitance value decrease caused by an excessively thick dielectric layer between the first electrode layer 401 and the second electrode layer 402.

In a specific embodiment, the PECVD has a good surface filling capability but a weak hole filling capability. The second dielectric layer 302 is formed on the surface of the first dielectric layer 301, so that due to the characteristics of the PECVD, the thickness H1 of the first sub-dielectric layer 3021 that is on the surface of the substrate 10 is greater than the thickness of the second sub-dielectric layer 3022 in the first trench 201. The thickness H1 of the first sub-dielectric layer 3021 is greater than the thickness of the second sub-dielectric layer 3022. That is, the first sub-dielectric layer 3021 located on the surface of the substrate 10 has a relatively large thickness. Originally, current leakage easily occurs between an upper electrode plate and a lower electrode plate at an edge of a trench capacitor. In this application, the second dielectric layer 302 is formed on the first dielectric layer 301, and the first sub-dielectric layer 3021 located on the surface of the substrate has a relatively large thickness, so that the dielectric layer between the first electrode layer 401 and the second electrode layer 402, which is originally easily subjected to current leakage, has an increased thickness. This improves isolation performance between the first electrode layer 401 and the second electrode layer 402, and prevents the generation of a leakage current. In this application, the thickness H1 of the first sub-dielectric layer 3021 is greater than the thickness H2 of the second sub-dielectric layer 3022, and the thickness of the second sub-dielectric layer 3022 gradually decreases from the top of the second sub-dielectric layer 3022 to the bottom of the first trench 201. This is because the PECVD has a weak filling capability in the first trench 201. That is, the second sub-dielectric layer 3022 is less filled in the first trench 201, and the thickness of the second sub-dielectric layer 3022 gradually decreases from the top of the second sub-dielectric layer 3022 to the bottom of the first trench 201. For a person skilled in the art, a formula for determining capacitance is C=εS/4πkd, where ε denotes a dielectric constant of the dielectric layer, k denotes an electrostatic force constant, S denotes an overlapping projection area of the electrode plates, and d denotes a distance between the electrode plates. This formula is configured to calculate a capacitance value under a given dielectric layer, area, and distance. The capacitance of the capacitor is not only related to areas of the electrode plates, but also related to the thickness of the dielectric layer. Therefore, a smaller thickness indicates a larger capacitance value, and a larger thickness indicates a smaller capacitance value. In this application, the PECVD has a weak hole filling capability in the first trench 201, so that the thickness of the second sub-dielectric layer 3022 deposited in the first trench 201 is relatively small, and the thickness of the second sub-dielectric layer 3022 gradually decreases from the top of the second sub-dielectric layer 3022 to the bottom of the first trench 201, to ensure the capacitance value of the trench capacitor 100. That is, this application can not only solve the problem of current leakage between the first electrode layer 401 and the second electrode layer 402, but also ensure the capacitance value of the trench capacitor 100, thereby preventing the problem of capacitance value decrease caused by an excessively thick dielectric layer between the first electrode layer 401 and the second electrode layer 402.

FIG. 18 to FIG. 23 are process flowcharts of a method for forming a contact structure according to an embodiment of the present disclosure.

Specifically, referring to FIG. 18, a fourth dielectric layer 304 is formed. The fourth dielectric layer 304 covers the third dielectric layer 303, the extension part 4011, and part of the substrate 10. An initial opening 50′ is formed on the fourth dielectric layer 304. The initial opening 50′ includes a first initial opening 501′ and a second initial opening 502′, and an opening dimension D1 of the first initial opening 501′ is greater than an opening dimension D2 of the second initial opening 502′.

Next, referring to FIG. 19 to FIG. 22, a fifth dielectric layer 305 is formed on the fourth dielectric layer 304. The fifth dielectric layer 305 fills the second initial opening 502′ and covers a sidewall and a bottom of the first initial opening 501′, and the remaining first initial opening 501′ serves as a third initial opening 503′. Etching is performed along the third initial opening 503′ to form a third opening 503. A fourth initial opening 504′ is formed on the second side. The fourth initial opening 504′ has an opening dimension smaller than that of the third initial opening 503′. Etching continues to be performed along the fourth initial opening 504′ to form a fourth opening 504. The third opening 503 exposes the extension part 4011, and the fourth opening exposes the second sub-electrode layer on the second side 4022. The fifth dielectric layer 305 may be made of silicon nitride, silicon oxide, or silicon oxynitride.

Next, referring to FIG. 23, the third opening 503 and the fourth opening 504 are filled with a conductive material to form a first contact structure 601 and a second contact structure 602. The first contact structure 601 is electrically connected to the extension part 4011, and the second contact structure 602 is electrically connected to a second sub-electrode layer 4022 on the second side. The first contact structure 601 has a depth greater than that of the second contact structure 602, and the first contact structure 601 and the second contact structure 602 form the contact structure 60 together.

This embodiment of this application is different from the previous embodiment in the following. In this embodiment of this application, the third opening 503 and the fourth opening 504 can be formed separately. Because etching depths of the third opening 503 and the fourth opening 504 are different and the first electrode layer 401 and the second sub-electrode layer 4022 each have a small thickness, simultaneous forming of the third opening 503 and the fourth opening 504 through etching may lead to over-etching of the first electrode layer 401 and the second sub-electrode layer 4022, which may lead to inaccurate connection of the contact structure 60. Step-by-step etching can separately control etching stop points of the third opening 503 and the fourth opening 504 to prevent over-etching, so that the first contact structure 601 is electrically connected to the extension part 4011 accurately, and the second contact structure 602 is electrically connected to the second sub-electrode layer 4022 on the second side accurately. In a specific embodiment, both the fifth dielectric layer 305 and the fourth dielectric layer 304 may be made of silicon oxide. During forming of the third opening 503 through etching, the extension part 4011 can be exposed by one-step etching of the silicon oxide without replacing an etching gas, thereby simplifying the process flow. In addition, the fourth dielectric layer 304 exists between the third opening 503 and a capacitor structure layer 4 adjacent thereto, and the existence of the fourth dielectric layer 304 can also prevent a breakdown effect that may occur when a voltage is applied to the first contact structure 601.

FIG. 24 is a schematic diagram of a trench capacitor according to an embodiment of the present disclosure.

Specifically, referring to FIG. 24, understanding is performed with reference to FIG. 9 to FIG. 13 for a clearer representation. The trench capacitor 100 includes: a substrate 10, where the substrate 10 has a first trench 201; a first electrode layer 401, covering the first trench 201 and part of a surface of the substrate 10; a first dielectric layer 301, covering the first electrode layer 401; a second dielectric layer 302, covering the first dielectric layer 301, where the second dielectric layer 302 includes a first sub-dielectric layer 3021 located on the surface of the substrate 10 and a second sub-dielectric layer 3022 located in the first trench 201, and the first sub-dielectric layer 3021 has a thickness greater than that of the second sub-dielectric layer 3022; a second electrode layer 402, covering the second dielectric layer 302; and a third dielectric layer 303, covering the second electrode layer 402 and filling the remaining first trench 201. In a specific embodiment, the thickness of the second sub-dielectric layer 3022 gradually decreases from a top of the second sub-dielectric layer 3022 to a bottom of the first trench 201. The second electrode layer 402 includes a first sub-electrode layer 4021 and a second sub-electrode layer 4022. The first sub-electrode layer 4021 is located on a surface of the second dielectric layer 302, and the second sub-electrode layer 4022 covers the first sub-electrode layer 4021. A dielectric constant of the first dielectric layer 301 is greater than that of the second dielectric layer 302. In a specific embodiment, the first dielectric layer 301 may be made of one or more of hafnium oxide, zirconium oxide, hafnium silicate, hafnium zirconate, lanthanum oxide, lanthanum silicate, barium strontium titanate, or lanthanum aluminate. The second dielectric layer 302 may be made of one or more of silicon oxide, silicon nitride, or silicon oxynitride. In a specific embodiment, the dielectric constant of hafnium oxide is about 20, which is much higher than that of silicon dioxide being 3.9. The trench capacitor further includes an initial dielectric layer 301′ between the first electrode layer 401 and the substrate 10. The initial dielectric layer 301′ covers the first trench 201 and part of the surface of the substrate 10. The first electrode layer 401, the second electrode layer 402, the first dielectric layer 301, the second dielectric layer 302, and the initial dielectric layer 301′ form a capacitor structure layer 4 together. The capacitor structure layer 4 includes a first capacitor structure layer 41 located on the surface of the substrate 10 and a second capacitor structure layer 42 located in the first trench. The first capacitor structure layer 41 includes a first side S1 and a second side S2, and the first side S1 and the second side S2 are located on both sides of the first trench 201 respectively. A length of the first side S1 in a direction parallel to the substrate 10 is greater than a length of the second side in the direction parallel to the substrate 10. The first electrode layer 401 on the first side S1 has an extension part 4011 in a direction parallel to the substrate 10. The trench capacitor 100 further includes a fourth electrode layer 304. The fourth dielectric layer 304 covers the third dielectric layer 303, the extension part 4011, and part of the substrate 10. The trench capacitor 100 further includes a contact structure 60, and the contact structure 60 includes a first contact structure 601 and a second contact structure 602. The first contact structure 601 penetrates through the fourth dielectric layer 304 to be electrically connected to the extension part 4011, and the second contact structure 602 penetrates through the fourth dielectric layer 304 and the third dielectric layer 303 to be electrically connected to a second sub-electrode layer 4022 on the second side S2. The first contact structure 601 has a depth greater than that of the second contact structure 602. A width C1 of the first contact structure 601 is greater than a width C2 of the second contact structure 602.

In this embodiment, the second dielectric layer 302 is formed on the surface of the first dielectric layer 301, and the thickness H1 of the first sub-dielectric layer 3021 is greater than that of the second sub-dielectric layer 3022, that is, the first sub-dielectric layer 3021 located on the surface of the substrate 10 has a relatively large thickness, so that the dielectric layer between the first electrode layer 401 and the second electrode layer 402, which is originally easily subjected to current leakage, has an increased thickness. This improves isolation performance between the first electrode layer 401 and the second electrode layer 402, and prevents the generation of a leakage current. In this application, the thickness H1 of the first sub-dielectric layer 3021 is greater than the thickness H2 of the second sub-dielectric layer 3022, and the thickness of the second sub-dielectric layer 3022 gradually decreases from the top of the second sub-dielectric layer 3022 to the bottom of the first trench 201. For a person skilled in the art, a formula for determining capacitance is C=εS/4πkd, where ε denotes a dielectric constant of the dielectric layer, k denotes an electrostatic force constant, S denotes an overlapping projection area of the electrode plates, and d denotes a distance between the electrode plates. This formula is configured to calculate a capacitance value under a given dielectric layer, area, and distance. The capacitance of the capacitor is not only related to areas of the electrode plates, but also related to the thickness of the dielectric layer. Therefore, a smaller thickness indicates a larger capacitance value, and a larger thickness indicates a smaller capacitance value. In this application, the PECVD has a weak hole filling capability in the first trench 201, so that the thickness of the second sub-dielectric layer 3022 deposited in the first trench 201 is relatively small, and the thickness of the second sub-dielectric layer 3022 gradually decreases from the top of the second sub-dielectric layer 3022 to the bottom of the first trench 201, to ensure the capacitance value of the trench capacitor 100. That is, this application can not only solve the problem of current leakage between the first electrode layer 401 and the second electrode layer 402, but also ensure the capacitance value of the trench capacitor 100, thereby preventing the problem of capacitance value decrease caused by an excessively thick dielectric layer between the first electrode layer 401 and the second electrode layer 402.

FIG. 25 is a schematic diagram of a package structure according to an embodiment of the present disclosure.

Specifically, referring to FIG. 25, the package structure includes a circuit board 110, a package substrate 120, an adapter board 130, and a memory 140. The package substrate 120 is located on the circuit board 110. The adapter board 130 includes the aforementioned trench capacitor 100. The memory 140 is located on the adapter board 130, and the memory 140 is electrically connected to the adapter board 130.

A person of ordinary skill in the art may understand that the foregoing implementations are specific embodiments for implementing the present disclosure. In an actual application, various modifications may be made to the forms and details of the implementations without departing from the spirit and scope of the present disclosure. Any person skilled in the art may make changes and modifications without departing from the spirit and scope of the present disclosure. Therefore, the protection scope of the present disclosure shall be subject to the scope defined by the claims.

What is claimed is:

1. A method for manufacturing a trench capacitor, comprising:
providing a substrate, the substrate having a first trench;
forming a first electrode layer in the first trench, the first electrode layer covering the first trench and a surface of the substrate;
forming a first dielectric layer, the first dielectric layer covering the first electrode layer;
forming a second dielectric layer, the second dielectric layer covering at least the first dielectric layer on the surface of the substrate, and the second dielectric layer having a thickness greater than that of the first dielectric layer;
forming a second electrode layer on the second dielectric layer, the second electrode layer covering the second dielectric layer; and
forming a third dielectric layer, the third dielectric layer filling the remaining first trench.

2. The method for manufacturing a trench capacitor according to claim 1, wherein the second dielectric layer comprises a first sub-dielectric layer located on the surface of the substrate and a second sub-dielectric layer located in the first trench; the first sub-dielectric layer has a thickness greater than that of the second sub-dielectric layer; and the thickness of the second sub-dielectric layer gradually decreases from a top of the second sub-dielectric layer to a bottom of the first trench.

3. The method for manufacturing a trench capacitor according to claim 1, wherein the second dielectric layer is formed by a first deposition process, and the first deposition process is plasma enhanced chemical vapor deposition.

4. The method for manufacturing a trench capacitor according to claim 1, wherein the second electrode layer comprises a first sub-electrode layer and a second sub-electrode layer, the first sub-electrode layer is formed on a surface of the second dielectric layer, and the second sub-electrode layer covers the first sub-electrode layer.

5. The method for manufacturing a trench capacitor according to claim 1, wherein a dielectric constant of the first dielectric layer is greater than that of the second dielectric layer.

6. The method for manufacturing a trench capacitor according to claim 4, before the forming a first electrode layer, the method further comprising: forming an initial dielectric layer, the initial dielectric layer covering the first trench and the surface of the substrate.

7. The method for manufacturing a trench capacitor according to claim 6, wherein the first electrode layer, the second electrode layer, the first dielectric layer, the second dielectric layer, and the initial dielectric layer form a capacitor structure layer together; after the forming a third dielectric layer, the method further comprises: removing part of the capacitor structure layer and part of the third dielectric layer on both sides of the first trench to expose part of the substrate; the remaining capacitor structure layer comprises a first capacitor structure layer located on the surface of the substrate and a second capacitor structure layer located in the first trench; the first capacitor structure layer comprises a first side and a second side, and the first side and the second side are located on both sides of the first trench respectively; and a length of the first side in a direction parallel to the substrate is greater than a length of the second side in the direction parallel to the substrate.

8. The method for manufacturing a trench capacitor according to claim 7, further comprising: removing part of the second electrode layer, the first dielectric layer, the second dielectric layer, and the third dielectric layer on the first side, to expose the first electrode layer, the exposed first electrode layer serving as an extension part.

9. The method for manufacturing a trench capacitor according to claim 8, further comprising: forming a contact structure, the contact structure comprising a first contact structure and a second contact structure, the first contact structure being electrically connected to the extension part, and the second contact structure being electrically connected to the second sub-electrode layer on the second side.

10. The method for manufacturing a trench capacitor according to claim 9, wherein the forming a contact structure specifically comprises: forming a fourth dielectric layer, the fourth dielectric layer covering the third dielectric layer, the extension part, and part of the substrate;
forming an initial opening on the fourth dielectric layer, the initial opening comprising a first initial opening and a second initial opening, and the first initial opening having an opening dimension greater than that of the second initial opening; continuing to perform etching along the initial opening to form a first opening and a second opening, the first opening exposing the extension part, and the second opening exposing the second sub-electrode layer on the second side; and filling the first opening and the second opening with a conductive material to form the first contact structure and the second contact structure, the first contact structure having a depth greater than that of the second contact structure, and the first contact structure and the second contact structure forming the contact structure together.

11. The method for manufacturing a trench capacitor according to claim 9, wherein the forming a contact structure specifically comprises: forming a fourth dielectric layer, the fourth dielectric layer covering the third dielectric layer, the extension part, and part of the substrate;
forming an initial opening on the fourth dielectric layer, the initial opening comprising a first initial opening and a second initial opening, and the first initial opening having an opening dimension greater than that of the second initial opening; forming a fifth dielectric layer on the fourth dielectric layer, the fifth dielectric layer filling the second initial opening and covering a sidewall and a bottom of the first initial opening, and the remaining first initial opening serving as a third initial opening; performing etching along the third initial opening to form a third opening; forming a fourth initial opening on the second side, the fourth initial opening having an opening dimension smaller than that of the third initial opening; continuing to perform etching along the fourth initial opening to form a fourth opening, the third opening exposing the extension part, and the fourth opening exposing the second sub-electrode layer on the second side; and filling the third opening and the fourth opening with a conductive material to form the first contact structure and the second contact structure, the first contact structure having a depth greater than that of the second contact structure, and the first contact structure and the second contact structure forming the contact structure together.

12. A trench capacitor, comprising:
a substrate, the substrate having a first trench;
a first electrode layer, the first electrode layer covering the first trench and part of a surface of the substrate;
a first dielectric layer, the first dielectric layer covering the first electrode layer;
a second dielectric layer, the second dielectric layer covering at least the first dielectric layer on the surface of the substrate, and the second dielectric layer having a thickness greater than that of the first dielectric layer;
a second electrode layer, the second electrode layer covering the second dielectric layer; and
a third dielectric layer, the third dielectric layer covering the second electrode layer and filling the remaining first trench.

13. The trench capacitor according to claim 12, wherein the second dielectric layer comprises a first sub-dielectric layer located on the surface of the substrate and a second sub-dielectric layer located in the first trench; the first sub-dielectric layer has a thickness greater than that of the second sub-dielectric layer; and the thickness of the second sub-dielectric layer gradually decreases from a top of the second sub-dielectric layer to a bottom of the first trench.

14. The trench capacitor according to claim 12, wherein the second electrode layer comprises a first sub-electrode layer and a second sub-electrode layer, the first sub-electrode layer is located on a surface of the second dielectric layer, and the second sub-electrode layer covers the first sub-electrode layer.

15. The trench capacitor according to claim 12, wherein a dielectric constant of the first dielectric layer is greater than that of the second dielectric layer.

16. The trench capacitor according to claim 14, further comprising: an initial dielectric layer between the first electrode layer and the substrate, the initial dielectric layer covering the first trench and part of the surface of the substrate.

17. The trench capacitor according to claim 16, wherein the first electrode layer, the second electrode layer, the first dielectric layer, the second dielectric layer, and the initial dielectric layer form a capacitor structure layer together; the capacitor structure layer comprises a first capacitor structure layer located on the surface of the substrate and a second capacitor structure layer located in the first trench; the first capacitor structure layer comprises a first side and a second side, and the first side and the second side are located on both sides of the first trench respectively; a length of the first side in a direction parallel to the substrate is greater than a length of the second side in the direction parallel to the substrate; and the first electrode layer on the first side has an extension part in the direction parallel to the substrate.

18. The trench capacitor according to claim 17, further comprising a fourth electrode layer, the fourth dielectric layer covering the third dielectric layer, the extension part, and part of the substrate.

19. The trench capacitor according to claim 18, further comprising a contact structure, the contact structure comprising a first contact structure and a second contact structure, the first contact structure penetrating through the fourth dielectric layer to be electrically connected to the extension part, and the second contact structure penetrating through the fourth dielectric layer and the third dielectric layer to be electrically connected to the second sub-electrode layer on the second side; and the first contact structure has a depth greater than that of the second contact structure.

20. A package structure, comprising:
a circuit board;
a package substrate, the package substrate being located on the circuit board;
an adapter board, the adapter board comprising the trench capacitor according to claim 12; and
a memory, the memory being located on the adapter board, and the memory being electrically connected to the adapter board.
